(19) United States
(12) Patent Application Publication
(10) Pub. No.: US 2017/0162708 A1
(43) Pub. Date: Jun. 8, 2017

(54) TFT SUBSTRATES AND THE MANUFACTURING METHODS THEREOF

(71) Applicant: Shezhen China Star Optoelectronics Technology Co., Ltd., Shenzhen, Guangdong (CN)

(72) Inventor: Shimin GE, Shenzhen, Guangdong (CN)

(73) Assignee: Shenzhen China Star Optoelectronics Technology Co. Ltd., Shenzhen, Guangdong (CN)

(21) Appl. No.: 14/786,459

(22) PCT Filed: Oct. 8, 2015
(86) PCT No.: PCT/CN2015/091440

§ 371 Date: Oct. 22, 2015

(30) Foreign Application Priority Data
Sep. 28, 2015 (CN) 201510629393.7

(51) Int. Cl. H01L 29/786; G02F 1/1362

(52) U.S. Cl. CPC H01L 29/78663; G02F 1/136277; G02F 2001/136295

(57) ABSTRACT

The TFT array substrate and the manufacturing method thereof are disclosed. The dual-layer structure having the bottom gate electrode, including the metal layer and the transparent metal oxide layer, and the common electrode, including the common electrode, may be formed by the same masking process. In this way, the number of masking processes may be decreased so as to enhance the manufacturing efficiency and the cost.

### BACKGROUND OF THE INVENTION

1. Field of the Invention

The present disclosure relates to liquid crystal display technology, and more particularly to a TFT array substrate and the manufacturing method thereof.

2. Discussion of the Related Art

Active Matrix LCD display technology utilizes the bi-directional polarization attributes of liquid crystals. The alignment of the liquid crystal molecules are controlled by the applied electrical field to implement the switch functions of optical paths of the backlight source. The LCD display modes may include TN, VA and IPS modes in accordance with the directions of the applied electrical field. Regarding VA mode, the vertical electrical field is applied to the liquid crystal molecules. Regarding IPS mode, the horizontal electrical field is applied to the liquid crystal molecules. However, IPS mode may further include IPS mode and FPS mode in accordance with the applied horizontal electrical field. With respect to the FFS mode, each of the pixel cells includes two electrode arranged respectively in an up layer and a down layer, i.e., a pixel electrode and a common electrode. In addition, the opening area of the common electrode in the down layer covers the whole surface. FFS mode has been widely adopted due to the attributes including high transmission rate, wide viewing angle and low color shift.

With respect to the active array display devices, usually, single-gate TFT is adopted. Compared to the Dual gate TFT, the single-gate TFT is characterized by the attributes such as high mobility, larger on-state current, smaller subthreshold swing, good Vth stability, and good uniformity. In addition, the stability of the grid bias is also better. However, more number of masking processes has to be performed in the manufacturing method of the traditional FFS mode of the dual-gate TFT array substrate, which increases the complexity of the manufacturing method and also the manufacturing cost.

### SUMMARY

The object of the invention is to a TFT array substrate and the manufacturing method thereof for reducing the number of masking processes so as to enhance the manufacturing efficiency and the cost.

In one aspect, a manufacturing method of TFT array substrates includes: providing a substrate; forming a first transparent metal oxide layer and a first metal layer on the substrate in turn, adopting a first masking process to etch the first transparent metal oxide layer and the first metal layer to be a bottom gate electrode and a common electrode, wherein the bottom gate electrode is of a dual-layer structure including the first metal layer and the first transparent metal oxide layer, the common electrode is of a single-layer structure having the first transparent metal oxide layer, and wherein the first mask is one of half-tone mask (HTM), gray-tone mask (GTM) and single slit mask (SSM); forming a gate insulation layer on the substrate; forming a semiconductor layer and a second metal layer on the substrate, adopting a second masking process to etch the semiconductor layer and the second metal layer to form a semiconductor pattern and a source electrode and a drain electrode at two ends of the semiconductor pattern, wherein the semiconductor pattern is above the bottom gate electrode; forming a passivation layer on the substrate, and adopting a third masking process to etch the passivation layer to form a through hole; and forming a second transparent metal oxide layer on the substrate, adopting a fourth masking process to etch the second transparent metal oxide layer to be a top gate electrode and at least one pixel electrode, the top gate electrode is above the semiconductor pattern, and a portion of the pixel electrode overlaps with the common electrode, and the pixel electrode electrically connects to the source electrode or the drain electrode via the through hole.

Wherein the step of forming a semiconductor layer and a second metal layer on the substrate, adopting a second masking process to etch the semiconductor layer and the second metal layer to form a semiconductor pattern and a source electrode and a drain electrode at two ends of the semiconductor pattern further includes: forming an intrinsic semiconductor layer, a doped semiconductor layer, and the second metal layer, adopting the second masking process to etch the intrinsic semiconductor layer to be an intrinsic pattern, to etch the doped semiconductor layer to be a first doped semiconductor pattern and a second doped semiconductor pattern, and to etch the second metal layer to be the drain electrode and the source electrode respectively above the first doped semiconductor pattern and the second doped semiconductor pattern, and the first doped semiconductor pattern and the second doped semiconductor pattern are at two ends of the intrinsic semiconductor layer.

Wherein the second mask is one of half-tone mask (HTM), gray-tone mask (GTM) and single slit mask (SSM).

In another aspect, a manufacturing method of TFT array substrates includes: providing a substrate; and forming a first transparent metal oxide layer and a first metal layer on the substrate in turn, adopting a first masking process to etch the first transparent metal oxide layer and the first metal layer to be a bottom gate electrode and a common electrode, wherein the bottom gate electrode is of a dual-layer structure including the first metal layer and the first transparent metal oxide layer, the common electrode is of a single-layer structure having the first transparent metal oxide layer.

Wherein the first mask is one of half-tone mask (HTM), gray-tone mask (GTM) and single slit mask (SSM).

Wherein the manufacturing method further includes: forming a gate insulation layer on the substrate; forming a semiconductor layer on the substrate, adopting a second masking process to etch the semiconductor layer to form a semiconductor pattern above the bottom gate; forming a second metal layer on the substrate, adopting a third masking process to etch the second metal layer to be a source electrode and a drain electrode at two ends of the semiconductor pattern; forming a passivation layer on the substrate, and adopting a fourth masking process to etch the passivation layer to form a through hole; and forming a second transparent metal oxide layer on the substrate, adopting a fifth masking process to etch the second transparent metal oxide layer to be a top gate electrode and at least one pixel electrode, the top gate electrode is above the semiconductor pattern, and a portion of the pixel electrode overlaps with the common electrode, and the pixel electrode electrically connects to the source electrode or the drain electrode via the through hole.

Wherein the method further includes a step after the step of forming a semiconductor layer on the substrate, adopting a second masking process to etch the semiconductor layer and before the step of forming a second metal layer on the substrate, adopting a third masking process to etch the second metal layer to be a source electrode and a drain electrode at two ends of the semiconductor pattern, and the step includes: forming an etch blocking layer on the substrate, and adopting a sixth masking process to etch the etch blocking layer to form through holes on the etch blocking layer at two ends of the semiconductor pattern.

Wherein the method further includes: forming a gate insulation layer on the substrate; forming a semiconductor layer and a second metal layer on the substrate, adopting a second masking process to etch the semiconductor layer and the second metal layer to form a semiconductor pattern and a source electrode and a drain electrode at two ends of the semiconductor pattern, wherein the semiconductor pattern is above the bottom gate electrode; forming a passivation layer on the substrate, and adopting a third masking process to etch the passivation layer to form a through hole; and forming a second transparent metal oxide layer on the substrate, adopting a fourth masking process to etch the second transparent metal oxide layer to be a top gate electrode and at least one pixel electrode, the top gate electrode is above the semiconductor pattern, and a portion of the pixel electrode overlaps with the common electrode, and the pixel electrode electrically connects to the source electrode or the drain electrode via the through hole.

Wherein the step of forming a semiconductor layer and a second metal layer on the substrate, adopting a second masking process to etch the semiconductor layer and the second metal layer to form a semiconductor pattern and a source electrode and a drain electrode at two ends of the semiconductor pattern further includes: forming an intrinsic semiconductor layer, a doped semiconductor layer, and the second metal layer, adopting the second masking process to etch the intrinsic semiconductor layer to be an intrinsic pattern, to etch the doped semiconductor layer to be a first doped semiconductor pattern and a second doped semiconductor pattern, and to etch the second metal layer to be the drain electrode and the source electrode respectively above the first doped semiconductor pattern and the second doped semiconductor pattern, and the first doped semiconductor pattern and the second doped semiconductor pattern are at two ends of the intrinsic semiconductor layer.

Wherein the second mask is one of half-tone mask (HTM), gray-tone mask (GTM) and single slit mask (SSM).

In another aspect, a TFT substrate includes: a substrate; and a bottom gate electrode and a common electrode on the substrate formed by the same masking process, the bottom gate electrode is of a dual-layer structure including the first metal layer and the first transparent metal oxide layer, and the common electrode is of a single-layer structure having the first transparent metal oxide layer.

Wherein the semiconductor pattern includes an intrinsic semiconductor pattern and a first doped semiconductor pattern and a second doped semiconductor pattern at two ends of the intrinsic semiconductor layer, and a drain electrode and a source electrode are respectively above the first doped semiconductor pattern and the second doped semiconductor pattern.

In view of the above, the dual-layer structure having the bottom gate electrode, including the metal layer and the transparent metal oxide layer, and the common electrode, including the common electrode, may be formed by the same masking process. In this way, the number of masking processes may be decreased so as to enhance the manufacturing efficiency and the cost.

### BRIEF DESCRIPTION OF THE DRAWINGS

FIG. 1 is a flowchart of the manufacturing method of the TFT array substrate in accordance with a first embodiment.

FIGS. 2A-2F are the schematic views of the bottom electrode and the common electrode of the array substrate manufactured by the method of FIG. 1.

FIG. 3 is a schematic view illustrating the light transmission principle of the first mask in accordance with the embodiment of FIG. 1.

FIG. 4 is a schematic view of the semiconductor pattern formed by the second masking process of the TFT array substrate of FIG. 1.

FIG. 5 is a schematic view of the source electrode and the drain electrode formed by the third masking process of the TFT array substrate of FIG. 1.

FIG. 6 is a schematic view of the through hole formed by the fourth masking process of the TFT array substrate of FIG. 1.

FIG. 7 is a schematic view of the TFT array substrate formed by the manufacturing method in the first embodiment, as shown in FIG. 1.

FIG. 8 is a flowchart of the manufacturing method of the TFT array substrate in accordance with a second embodiment.

FIG. 9 is a schematic view of the TFT array substrate formed by the manufacturing method in the second embodiment, as shown in FIG. 8.

FIG. 10 is a flowchart of the manufacturing method of the TFT array substrate in accordance with a third embodiment.

FIGS. 11A-11D are the schematic views of the semiconductor pattern, the source and the drain of the array substrate manufactured by the method of FIG. 10.

FIG. 12 is a schematic view of the TFT array substrate formed by the manufacturing method in the second embodiment, as shown in FIG. 10.

### DETAILED DESCRIPTION OF THE EMBODIMENTS

Embodiments of the invention will now be described more fully hereinafter with reference to the accompanying drawings, in which embodiments of the invention are shown.

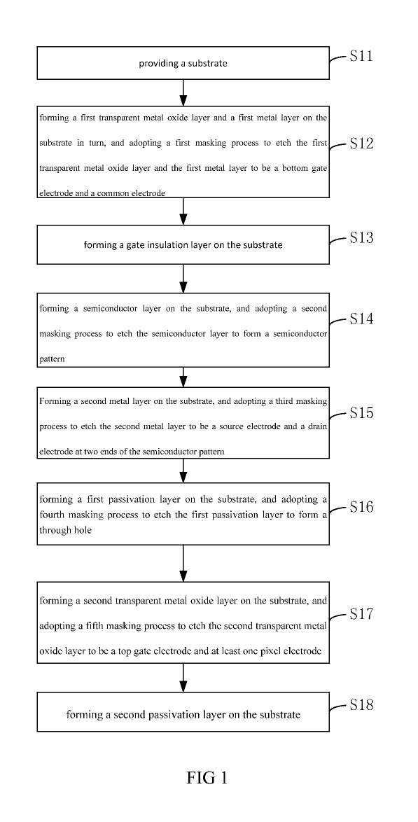

FIG. 1 is a flowchart of the manufacturing method of the TFT array substrate in accordance with a first embodiment. The method includes:

In block S11, a substrate is provided.

In block S12, a first transparent metal oxide layer and a first metal layer are formed on the substrate in turn, and the first masking process is adopted to etch the first transparent metal oxide layer and the first metal layer to be a bottom gate electrode and a common electrode. The substrate is a base substrate. The substrate may be a glass substrate, a plastic substrate or the substrate of other suitable materials. In the embodiment, the substrate is a translucent glass substrate.

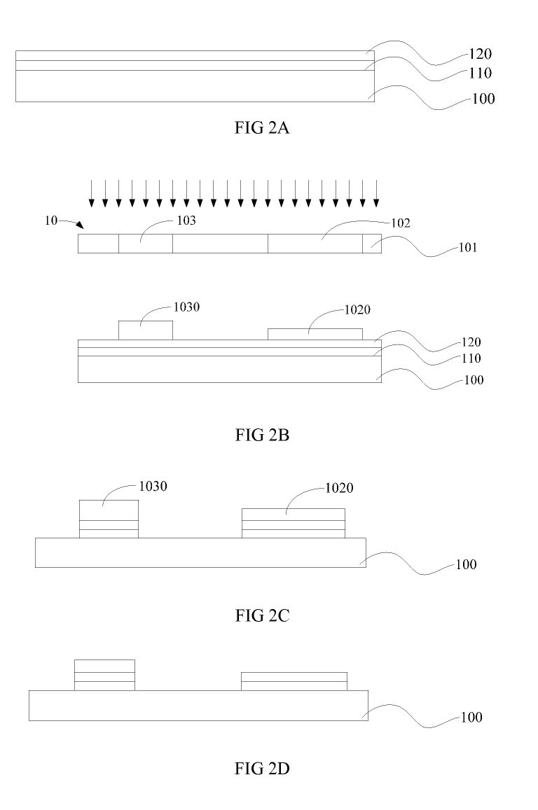

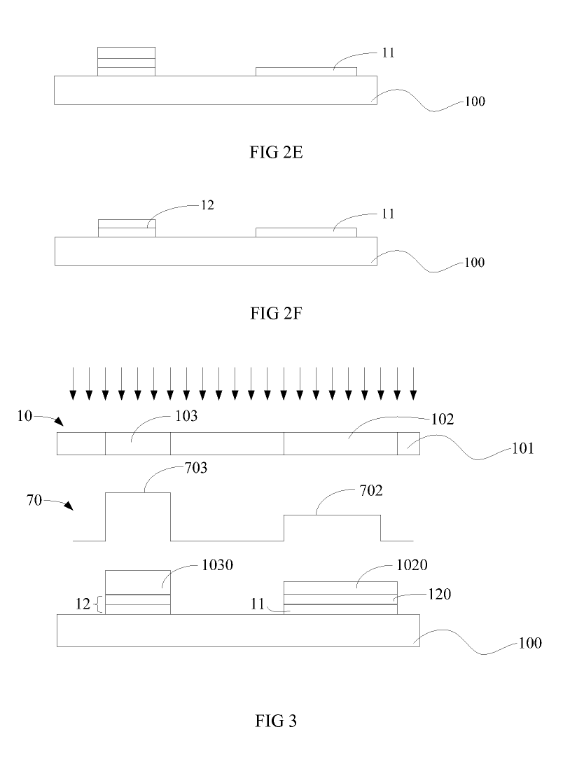

FIGS. 2A-2F are the schematic views of the bottom electrode and the common electrode of the array substrate manufactured by the method of FIG. 1. As shown in FIG. 2A, the first transparent metal oxide layer 110 and the first metal layer 120 are formed on the substrate 100 by PVD. The first metal layer 120 covers the first transparent metal oxide layer 110. The first metal oxide semiconductor layer may be made by Indium tin oxide (ITO), which is metal oxide having good conductance and transparency. The first metal layer 120 may be made by materials including, but not limited to, chromium, aluminum, titanium, or other metal materials.

As shown in FIG. 2B, the first mask 10 is adopted to expose the substrate 100 having the first metal layer 120 and the first transparent metal oxide layer 110. A photoresist layer (not shown) covers the first metal layer 120 in advance. The first mask 10 may be any one of half-tone mask (HTM), gray-tone mask (GTM) or single slit mask (SSM). The first mask 10 includes a light transmission portion 101, a translucent portion 102, and an opaque portion 103.

The first mask 10 is adopted to expose the substrate 100 having the first metal layer 120 first metal layer 120 and the first transparent metal oxide layer 110. Afterward, the area of the photoresist layer corresponding to the light transmission portion 101 of the first mask 10 has been fully exposed, the area of the photoresist layer corresponding to the translucent portion 102 of the first mask 10 has been semi-exposed, and the area of the photoresist layer corresponding to the opaque portion 103 of the first mask 10 has not been exposed. Thus, a first photoresist portion 1030 and a second photoresist portion 1020 are formed after the first mask 10 is adopted to expose, semi-expose, non-expose, and develop the photoresist layer. The thickness of the first photoresist portion 1030 is larger than the thickness of the second photoresist portion 1020. The first photoresist portion 1030 corresponds to the opaque portion 103 of the first mask 10, and the second photoresist portion 1020 corresponds to the translucent portion 102 of the first mask 10.

As shown in FIG. 2C, a first-time wetting etch process is applied to the areas of the first metal layer 120 and the first transparent metal oxide layer 110 that have not been covered by the first photoresist portion 1030 and the second photoresist portion 1020 so as to remove the areas of the first metal layer 120 and the passivation layer 130 that have not been covered by the first photoresist portion 1030 and the second photoresist portion 1020.

As shown in FIG. 2D, the oxygen is adopted to perform an ashing process to the first photoresist portion 1030 and the second photoresist portion 1020 so as to remove the second photoresist portion 1020 with smaller thickness, and the first metal layer 120 covered by the second photoresist portion 1020 are exposed. A portion of the first photoresist portion 1030 is maintained.

As shown in FIG. 2E, the wetting process is further applied to the exposed first metal layer 120. As such, the remaining first transparent metal oxide layer 110 operates as the a common electrode 11, which is of a single-layer structure made by the first transparent metal oxide layer 110.

As shown in FIG. 2F, the remaining first photoresist portion 1030 are striped, and the remaining first metal layer 120 and the first transparent metal oxide layer 110 are stacked together to form a bottom gate electrode 12. Thus, the masking process is performed once and the bottom gate electrode 12 and the common electrode 11 may be formed at the same time.

FIG. 3 is a schematic view illustrating the light transmission principle of the first mask in accordance with the embodiment of FIG. 1. To simply the description, the first mask 10, the optical strength curve 70, the structure of the bottom gate electrode 12 and the common electrode 11 formed on the substrate 100 will be explained at the same time. As shown in FIG. 3, the first mask 10 includes the light transmission portion 101, the translucent portion 102, and the opaque portion 103. The opaque portion 103 corresponds to the bottom gate electrode 12, the translucent portion 102 corresponds to the common electrode 11, and the light transmission portion 101 corresponds to other areas except the bottom gate electrode 12 and the common electrode 11. The optical strength curve 70 includes a first protrusive portion 703 corresponding to the opaque portion 103 of the first mask 10, which relates to a weakest optical strength. The optical strength curve 70 includes a second protrusive portion 702 corresponding to the translucent portion 102 of the first mask 10. The optical strength of the first protrusive portion 703 is smaller than that of the second protrusive portion 702. In addition, the optical strength of the first protrusive portion 703 and that of the second protrusive portion 702 are smaller than that of other areas. Thus, after the first mask 10 is adopted to perform the developing process, the thickness of the first photoresist portion 1030 on the bottom gate electrode 12 is larger than the thickness of the second photoresist portion 1020 on the common electrode 11. Further, the wetting etch process and the photoresist-oxygen ashing process are conducted to obtain the bottom gate electrode 12 and the common electrode 11. Thus, the bottom gate electrode 12 and the common electrode 11 may be formed at the same time with one masking process.

In the embodiment, the first mask 10 is adopted to expose, semi-expose, and non-expose the first transparent metal oxide layer 110 and the first metal layer 120 to form the bottom gate electrode 12 and the common electrode 11, which is determined by the structure of the first mask 10.

In block S13, a gate insulation layer is further formed on the substrate.

In block S14, a semiconductor layer is further formed on the substrate, and a second masking process is adopted to etch the semiconductor layer to form the semiconductor pattern.

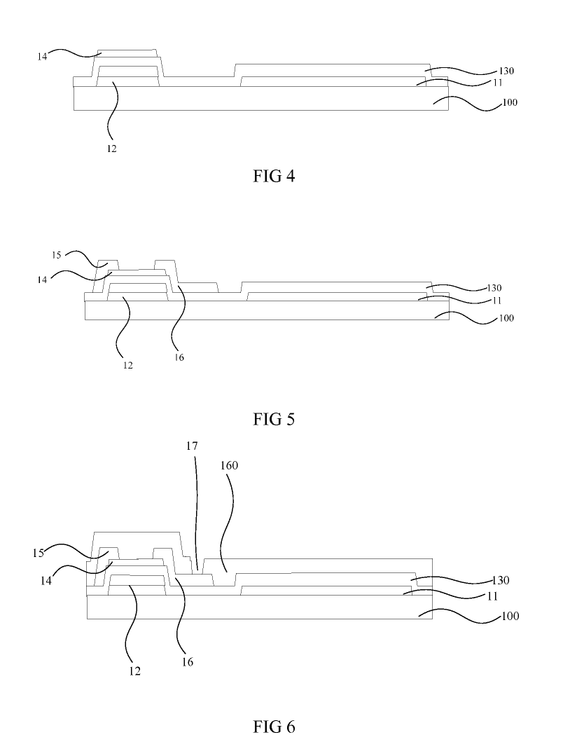

As shown in FIG. 4, a gate insulation layer 130 is formed on the substrate 100. The gate insulation layer 130 covers the bottom gate electrode 12 and the common electrode 11 and extends into the 100 and extends into the 100. The gate insulation layer 130 may be made by PVD. The gate insulation layer 130 may be made by materials including, but not limited to, SiNx, SiOx, and SiOxNy.

A semiconductor layer (not shown) is formed on the gate insulation layer 130 by a depositing method. The semiconductor layer may be made by Indium Gallium Zinc Oxide (IGZO), which is amorphous metal oxide including indium, gallium and zinc. The IGZO is the material of trench layers of newly developed thin film transistor. The carrier mobility ratio of the IGZO is about 20 to 30 times than the amorphous silicon, which can greatly enhance the charge-discharge rate of the TFT toward the pixel electrode. Also, the response speed of the pixel and the refresh rate are enhanced. At the same time, the row scanning rate of the pixels may has quickly response so as to realize high resolution in the TFT-LCD field. In addition, as the number of the transistors is decreased and the optical transmission rate of each of the pixels is enhanced, the IGZO display devices may have higher energy efficiency level and higher efficiency. In addition, IGZO may be manufactured by manufacturing lines of amorphous silicon with slight change. Thus, the competitiveness of the IGZO cost is higher than that of the low temperature poly silicon (LTPS).

A photoresist layer (not shown) covers the semiconductor layer. A second mask (not shown) is adopted to expose the photoresist layer. The second mask includes a light transmission portion and an opaque portion. The second masking process is adopted to conduct the exposure, development, and etching process, the semiconductor layer corresponding to the light transmission portion of the second mask is removed, and the semiconductor layer corresponding to the opaque portion is kept to form a semiconductor pattern 14. The semiconductor pattern 14 is formed by the semiconductor layer corresponding to the opaque portion of the second mask due to not being exposed and etched. The semiconductor pattern 14 is above the bottom gate electrode 12. The process of forming the semiconductor pattern 14 relates to conventional solution and is thus omitted hereinafter.

In block S15, a second metal layer is formed on the substrate, and a third masking process is adopted to each the second metal layer to be a source electrode and a drain electrode on two ends of the semiconductor pattern.

As shown in FIG. 5, the second metal layer (not shown) is formed on the substrate 100. A second mask (not shown) is adopted to expose, develop, and etch the second metal layer to from the source electrode 16 and the drain electrode 15 at two ends of the semiconductor pattern 14. The process of forming the drain electrode 15 and the source electrode 16 relates to conventional solution and is thus omitted hereinafter.

In block S16, a first passivation layer is formed on the substrate, and a fourth masking process is adopted to etch the first passivation layer to form a through hole.

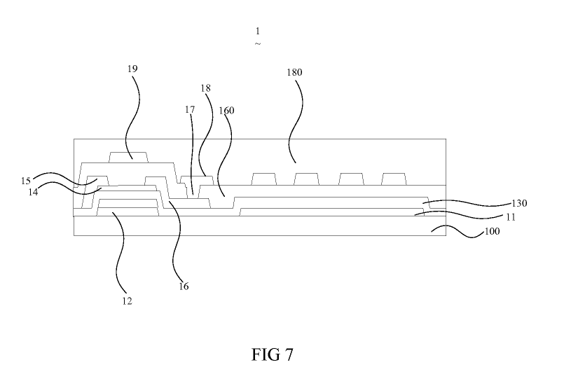

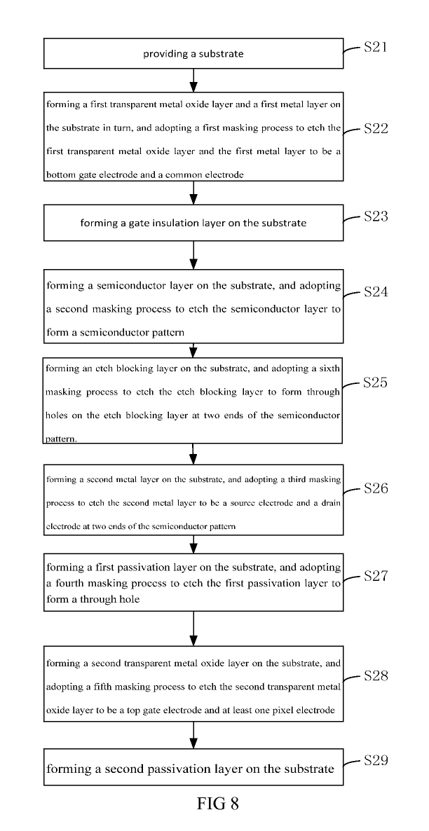

As shown in FIG. 6, a first passivation layer 160 is formed on the substrate 100. The first passivation layer 160 covers the source electrode 16 and the drain electrode 15. The semiconductor pattern 14 extends into the gate insulation layer 130. A fourth mask (not shown) is adopted to expose, develop, and etch the first passivation layer 160 so as to form the through hole 17 on the first passivation layer 160 corresponding to the source electrode 16 and the drain electrode 15. The process of forming the drain electrode 15 and the source electrode 16 relates to conventional solution and is thus omitted hereinafter.

In block S17, a second metal oxide semiconductor layer is formed on the substrate, and a fifth masking process is adopted to etch the second metal oxide semiconductor layer to be a top gate electrode and the pixel electrode.

In block S18, a second passivation layer is formed on the substrate.

FIG. 7 is a schematic view of the TFT array substrate formed by the manufacturing method in the first embodiment, as shown in FIG. 1. The blocks S17 and 18 may be described with reference to FIG. 7. The second metal oxide semiconductor layer (not shown) is formed on the first passivation layer 160 of the substrate 100. The second metal oxide semiconductor layer may be made by the same material with the common electrode 11. That is, the second metal oxide semiconductor layer may be made by ITO oxide. A fifth mask (not shown) is adopted to expose, etch, and develop the second metal oxide semiconductor layer to form the top gate electrode 19 and a plurality of pixel electrodes 18. The top gate electrode 19 is above the semiconductor pattern 14 and the top gate electrode 19 corresponds to the bottom gate electrode 12. At least a portion of the pixel electrode 18 is overlapped with the common electrode 11. At least one pixel electrode 18 electrically connects to one of the drain electrode 15 and the source electrode 16 via the through hole 17. As shown in FIG. 7, the pixel electrode 18 electrically connects to the source electrode 16 via the through hole 17, and other pixel electrodes 18 are arranged above the common electrode 11. The other pixel electrodes 18 are spaced apart from each other. A second passivation layer 180 is formed on the substrate 100. The second passivation layer 180 covers the pixel electrode 18, the top gate electrode 19, and the second passivation layer 180 extends into the first passivation layer 160.

The process of forming the pixel electrode 18 and the top gate electrode 19 by the second metal oxide semiconductor layer relates to conventional solution and is thus omitted hereinafter.

In view of the above, the TFT array substrate 1 includes the substrate 100, the bottom gate electrode 12 and the common electrode 11 on the substrate 100, the gate insulation layer 130, the semiconductor pattern 14, the drain electrode 15, the source electrode 16, the first passivation layer 160, the pixel electrode 18, the top gate electrode 19 and the second passivation layer 180. The bottom gate electrode 12 and the common electrode 11 are formed by the same masking process. In addition, the bottom gate electrode 12 is of a dual-layer structure including the first metal layer 120 and the first transparent metal oxide layer 110. The common electrode 11 is of a single-layer structure having the first transparent metal oxide layer 110. The gate insulation layer 130 covers the bottom gate electrode 12 and the common electrode 11 and extends into the substrate 100. The semiconductor pattern 14 is above the bottom gate electrode 12. The drain electrode 15 and the source electrode 16 are respectively arranged on two ends of the semiconductor pattern 14. The first passivation layer 160 covers the drain electrode 15, the source electrode 16, and the semiconductor pattern 14, and the first passivation layer 160 extends into the gate insulation layer 130. In addition, the first passivation layer 160 includes the through hole 17 corresponding to the source electrode 16 or the drain electrode 15. As shown in FIG. 7, the through hole 17 is above the source electrode 16, and the through hole 17 electrically connects the source electrode 16 with the pixel electrode 18. A portion of the pixel electrode 18 overlaps with the common electrode 11. The top gate electrode 19 is arranged to be opposite to the bottom gate electrode 12. The second passivation layer 180 covers the top gate electrode 19 and the pixel electrode 18 and extends into the first passivation layer 160. The TFT array substrate 1 is of the back channel etch (BCE) structure.

In view of the above, the metal layer and the transparent metal oxide layer are formed on the substrate in turn. Afterward, one masking process is adopted to form the bottom gate electrode and the common electrode on the substrate such that the dual-layer structure including the metal layer and the transparent metal oxide layer is formed as the bottom gate electrode, and the common electrode is of the single-layer structure having the transparent metal oxide layer. As such, the number of masking processes for forming the TFT array substrate may be reduced so as to enhance the manufacturing efficiency and the cost.

FIG. 8 is a flowchart of the manufacturing method of the TFT array substrate in accordance with a second embodiment. The method includes the following steps.

In block S21, a substrate is provided.

In block S22, a first transparent metal oxide layer and a first metal layer are formed on the substrate in turn, and the first masking process is adopted to etch the first transparent metal oxide layer and the first metal layer to be a bottom gate electrode and a common electrode.

In block S23, a gate insulation layer is further formed on the substrate.

In block S24, a semiconductor layer is further formed on the substrate, and a second masking process is adopted to etch the semiconductor layer to form the semiconductor pattern.

In block S25, an etch blocking layer is formed on the substrate, and a sixth masking process is adopted to etch the etch blocking layer to form through holes on the etch blocking layer at two ends of the semiconductor pattern.

In block S26, a second metal layer is formed on the substrate, and a third masking process is adopted to etch the second metal layer to be a source electrode and a drain electrode at two ends of the semiconductor pattern.

In block S27, a passivation layer is formed on the substrate, and a fourth masking process is adopted to etch the passivation layer to form a through hole.

In block S28, a second metal oxide semiconductor layer is formed on the substrate, and a fifth masking process is adopted to etch the second metal oxide semiconductor layer to form a top gate electrode and the pixel electrode.

In block S29, a second passivation layer is formed on the substrate.

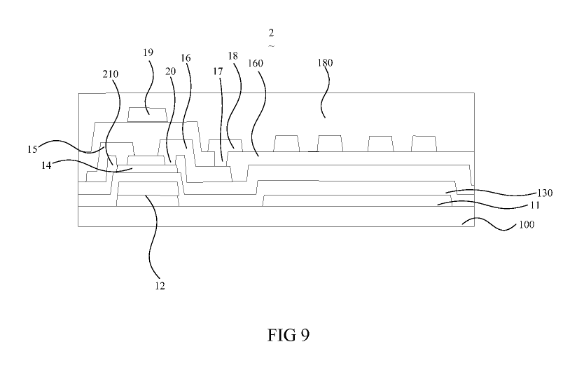

As shown in FIG. 4, after the semiconductor pattern 14 is formed by etching the semiconductor layer with the second mask, in the second embodiment, the etch blocking layer 210 is formed on the substrate 100. FIG. 9 is a schematic view of the TFT array substrate formed by the manufacturing method in the second embodiment, as shown in FIG. 8. The etch blocking layer 210 covers the semiconductor pattern 14 and extends into the gate insulation layer 130. The sixth mask (not shown) is adopted to expose, develop, and etch the etch blocking layer 210. The areas of the etch blocking layer 210 at two ends of the semiconductor pattern 14 are exposed and etched to form the through hole 20 of the etch blocking layer. The through hole 20 of the etch blocking layer is configured for electrically connecting the source electrode 16 and the drain electrode 15 to the semiconductor pattern 14. The etch blocking layer 210 prevents the semiconductor pattern 14 from being damaged during the formation of the source electrode 16 and the drain electrode 15. The blocks S26-S29 are similar to the blocks S15-S18, and thus are omitted hereinafter.

In the embodiment, the array substrate 2 may be of the Etch stopper layer (ESL) array substrate. The difference between the ESL array substrate 2 and the BCE array substrate 1 resides in that the ESL array substrate 2 may further includes the etch blocking layer 210 on the semiconductor pattern 14. The areas of the etch blocking layer 150 corresponding to two ends of the semiconductor pattern 14 are provided with the through holes of the etch blocking layer 20. As such, the source electrode 16 and the drain electrode 15 at two ends of the semiconductor layer may electrically connect to the semiconductor pattern 14 via the through hole 20 of the etch blocking layer.

In view of the above, the manufacturing process of the array substrate is similar to that in the first embodiment. In this way, the number of masking processes adopted during the manufacturing process of the array substrate is decreased, such that the manufacturing efficiency is enhanced and the manufacturing cost is reduced. In addition, by configuring the etch blocking layer, the semiconductor pattern is protected during the etching process is applied to the drain electrode and the source electrode.

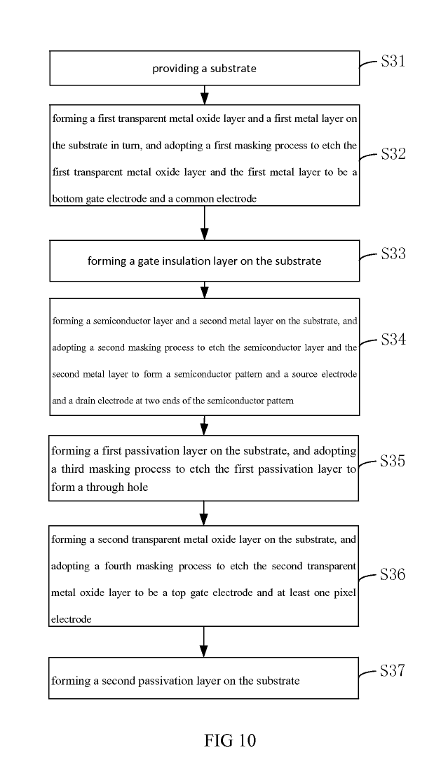

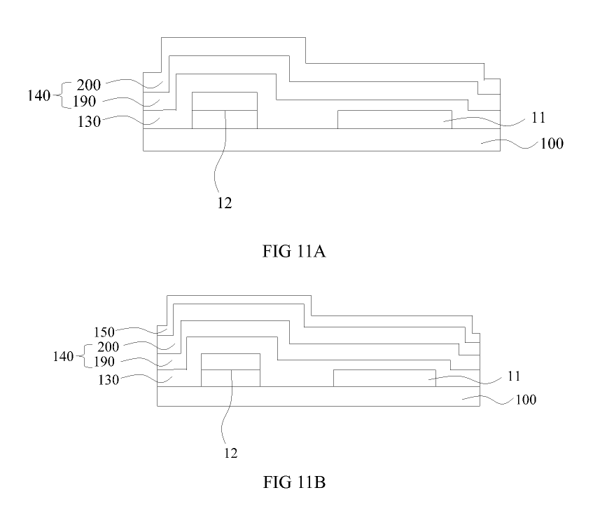

FIG. 10 is a flowchart of the manufacturing method of the TFT array substrate in accordance with a third embodiment. The method includes the following steps.

In block S31, a substrate is provided.

In block S32, a first transparent metal oxide layer and a first metal layer are formed on the substrate in turn, and the first masking process is adopted to etch the first transparent metal oxide layer and the first metal layer to be a bottom gate electrode and a common electrode.

In block S33, a gate insulation layer is further formed on the substrate.

The blocks S31-S33 are similar to the blocks S11-S13, and thus are omitted hereinafter.

In block S34, a semiconductor layer and a second metal layer are further formed on the substrate, and a second masking process is adopted to etch the semiconductor layer to form the semiconductor pattern and the source electrode and the drain electrode on two ends of the semiconductor pattern.

Also referring to FIGS. 1-5, FIGS. 11A-11D are the schematic views of the semiconductor pattern, the source and the drain of the array substrate manufactured by the method of FIG. 10. The third embodiment is similar to the first embodiment that the second passivation layer 140 is etched to form the semiconductor pattern 14, and the etch blocking layer 150 is etched to form the source electrode 16 and the drain electrode 15 at two ends of the semiconductor pattern 14. In addition, the semiconductor pattern 14 is above the bottom gate electrode 12.

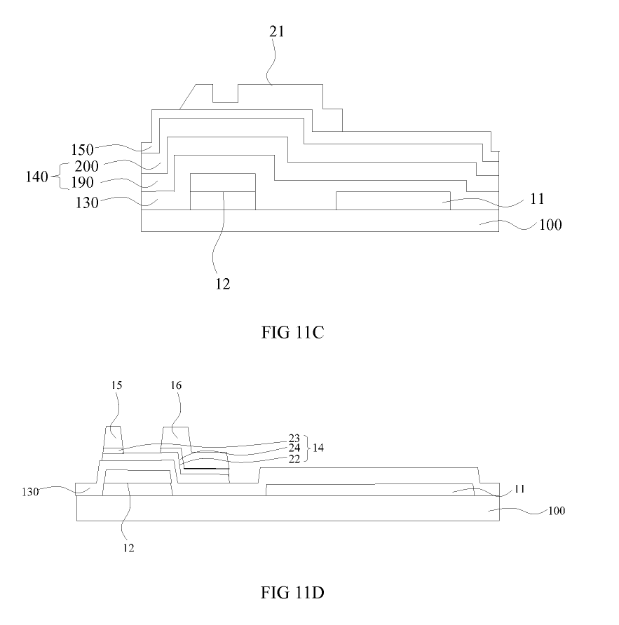

The difference between the first and the third embodiment resides in that, as shown in FIG. 11A, the second passivation layer 140 includes an intrinsic semiconductor layer 190 and a doped semiconductor layer 200. The CVD is adopted to deposit the intrinsic semiconductor layer 190 and the doped semiconductor layer 200 on the first mask 10 in turn. The intrinsic semiconductor layer 190 is an a-si layer, and the doped semiconductor layer 200 is a n+a-Si layer, which is a N-type amorphous-silicon-conductive layer having high-doping concentration.

As shown in FIG. 11B, PVD is adopted to deposit the second metal layer 150 on the substrate 100. The second metal layer 150 may be made by the same material in the first embodiment, such as aluminum chromium, molybdenum, titanium, or other metal materials.

Further, a photoresist layer (not shown) is formed on the second metal layer 150. The second mask is adopted to expose and develop the photoresist layer. The second mask is similar to the first mask, which may be any one of half-tone mask (HTM), gray-tone mask (GTM) and single slit mask (SSM). When the second mask is adopted to expose and develop the photoresist layer, a photoresist pattern 21 is obtained as shown in FIG. 11C. The area of the second metal layer 150 that has not been covered by the photoresist pattern 21 are removed by wet etching process. Afterward, the areas of the intrinsic semiconductor layer 190 and the doped semiconductor layer 200 that have not been covered by the photoresist pattern 21 are removed by dry etching process. Further, oxygen is adopted to apply an ashing process to the photoresist pattern 21 so as to remove the thinner portion of the photoresist pattern 21, that is, the thicker portion of the photoresist pattern 21 is maintained. It is to be noted that the thicker portion relates to the areas above the source electrode 16 and the drain electrode 15. Further, the second metal layer 150 that has not been covered by the photoresist are removed by the wet etching process, and the doped semiconductor layer 200 and the intrinsic semiconductor layer 190 that have not been covered by the photoresist are removed by the dry etching process. As such, the structure as shown in FIG. 11D is obtained, wherein the intrinsic semiconductor layer 190 is etched to obtain the intrinsic semiconductor pattern 22, and the doped semiconductor layer 200 is etched to obtain a first doped semiconductor pattern 23 and a second doped semiconductor pattern 24 at two ends of the intrinsic semiconductor pattern 22. The second metal layer 150 is etched to be the drain electrode 15 above the first doped semiconductor pattern 23 and the source electrode 16 above the second doped semiconductor pattern 24. Thus, in the embodiment, the semiconductor pattern 14, the drain electrode 15, and the source electrode 16 may be formed by the same masking process at the same time. The semiconductor pattern 14 includes the intrinsic semiconductor pattern 22 and the first doped semiconductor pattern 23 and the second doped semiconductor pattern 24 respectively at two ends of the intrinsic semiconductor pattern 22.

In block S35, a first passivation layer is formed on the substrate, and a third masking process is adopted to etch the first passivation layer to form a through hole.

In block S37, a second metal oxide semiconductor layer is formed on the substrate, and a fourth masking process is adopted to etch the second metal oxide semiconductor layer to be a top gate electrode and the pixel electrode.

In block S38, a second passivation layer is formed on the substrate.

Referring to FIGS. 6, 7 and 12, FIG. 12 is a schematic view of the TFT array substrate formed by the manufacturing method in the second embodiment, as shown in FIG. 10. The blocks S35-37 are similar to the blocks S16-S18, and thus are omitted hereinafter.

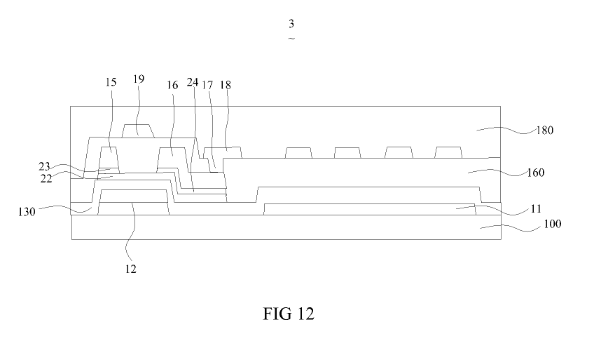

The difference between the TFT array substrate 3 of this embodiment and the TFT array substrate 1 of the first embodiment resides in: the intrinsic semiconductor pattern 22 and the first doped semiconductor pattern 23 and the second doped semiconductor pattern 24 at two ends of the intrinsic semiconductor pattern 22 may replace the semiconductor pattern 14 of FIG. 7. In addition, as shown in FIG. 12, the drain electrode 15 is above the first doped semiconductor pattern 23, and the source electrode 16 is above the second doped semiconductor pattern 24. Thus, the bottom gate electrode and the common electrode may be made on the TFT array substrate by the same masking process. In addition, the semiconductor pattern and the source electrode and the drain electrode at two ends of the semiconductor pattern may be made by same masking process, wherein the semiconductor pattern includes the intrinsic semiconductor layer and the first doped semiconductor pattern and the second doped semiconductor pattern at two ends of the intrinsic semiconductor layer. The drain electrode and the source electrode are respectively above the first doped semiconductor pattern and the second semiconductor pattern such that the TFT array substrate may include four masking processes. In this way, the number of masking processes is decreased, the manufacturing efficiency is enhanced, and the manufacturing cost is reduced.

In view of the above, the dual-layer structure having the bottom gate electrode, including the metal layer and the transparent metal oxide layer, and the common electrode, including the common electrode, may be formed by the same masking process. In this way, the number of masking processes may be decreased so as to enhance the manufacturing efficiency and the cost.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A manufacturing method of TFT array substrates, comprising:
providing a substrate;
forming a first transparent metal oxide layer and a first metal layer on the substrate in turn, adopting a first masking process to etch the first transparent metal oxide layer and the first metal layer to be a bottom gate electrode and a common electrode, wherein the bottom gate electrode is of a dual-layer structure comprising the first metal layer and the first transparent metal oxide layer, the common electrode is of a single-layer structure having the first transparent metal oxide layer, and wherein the first mask is one of half-tone mask (HTM), gray-tone mask (GTM) and single slit mask (SSM);
forming a gate insulation layer on the substrate;
forming a semiconductor layer and a second metal layer on the substrate, adopting a second masking process to etch the semiconductor layer and the second metal layer to form a semiconductor pattern and a source electrode and a drain electrode at two ends of the semiconductor pattern, wherein the semiconductor pattern is above the bottom gate electrode;
forming a passivation layer on the substrate, and adopting a third masking process to etch the passivation layer to form a through hole; and
forming a second transparent metal oxide layer on the substrate, adopting a fourth masking process to etch the second transparent metal oxide layer to be a top gate electrode and at least one pixel electrode, the top gate electrode is above the semiconductor pattern, and a portion of the pixel electrode overlaps with the common electrode, and the pixel electrode electrically connects to the source electrode or the drain electrode via the through hole.

2. The manufacturing method as claimed in claim 1, wherein the step of forming a semiconductor layer and a second metal layer on the substrate, adopting a second masking process to etch the semiconductor layer and the second metal layer to form a semiconductor pattern and a source electrode and a drain electrode at two ends of the semiconductor pattern further comprises:
forming an intrinsic semiconductor layer, a doped semiconductor layer, and the second metal layer, adopting the second masking process to etch the intrinsic semiconductor layer to be an intrinsic pattern, to etch the doped semiconductor layer to be a first doped semiconductor pattern and a second doped semiconductor pattern, and to etch the second metal layer to be the drain electrode and the source electrode respectively above the first doped semiconductor pattern and the second doped semiconductor pattern, and the first doped semiconductor pattern and the second doped semiconductor pattern are at two ends of the intrinsic semiconductor layer.

3. The manufacturing method as claimed in claim 2, wherein the second mask is one of half-tone mask (HTM), gray-tone mask (GTM) and single slit mask (SSM).

4. A manufacturing method of TFT array substrates, comprising:
providing a substrate; and
forming a first transparent metal oxide layer and a first metal layer on the substrate in turn, adopting a first masking process to etch the first transparent metal oxide layer and the first metal layer to be a bottom gate electrode and a common electrode, wherein the bottom gate electrode is of a dual-layer structure comprising the first metal layer and the first transparent metal oxide layer, the common electrode is of a single-layer structure having the first transparent metal oxide layer.

5. The manufacturing method as claimed in claim 4, wherein the first mask is one of half-tone mask (HTM), gray-tone mask (GTM) and single slit mask (SSM).

6. The manufacturing method as claimed in claim 4, wherein the manufacturing method further comprises:
forming a gate insulation layer on the substrate;
forming a semiconductor layer on the substrate, adopting a second masking process to etch the semiconductor layer to form a semiconductor pattern above the bottom gate;
forming a second metal layer on the substrate, adopting a third masking process to etch the second metal layer to be a source electrode and a drain electrode at two ends of the semiconductor pattern;
forming a passivation layer on the substrate, and adopting a fourth masking process to etch the passivation layer to form a through hole; and
forming a second transparent metal oxide layer on the substrate, adopting a fifth masking process to etch the second transparent metal oxide layer to be a top gate electrode and at least one pixel electrode, the top gate electrode is above the semiconductor pattern, and a portion of the pixel electrode overlaps with the common electrode, and the pixel electrode electrically connects to the source electrode or the drain electrode via the through hole.

7. The manufacturing method as claimed in claim 6, wherein the method further comprises a step after the step of forming a semiconductor layer on the substrate, adopting a second masking process to etch the semiconductor layer and before the step of forming a second metal layer on the substrate, adopting a third masking process to etch the second metal layer to be a source electrode and a drain electrode at two ends of the semiconductor pattern, and the step comprises:
forming an etch blocking layer on the substrate, and adopting a sixth masking process to etch the etch blocking layer to form through holes on the etch blocking layer at two ends of the semiconductor pattern.

8. The manufacturing method as claimed in claim 4, wherein the method further comprises: forming a gate insulation layer on the substrate;
forming a semiconductor layer and a second metal layer on the substrate, adopting a second masking process to etch the semiconductor layer and the second metal layer to form a semiconductor pattern and a source electrode and a drain electrode at two ends of the semiconductor pattern, wherein the semiconductor pattern is above the bottom gate electrode;
forming a passivation layer on the substrate, and adopting a third masking process to etch the passivation layer to form a through hole; and
forming a second transparent metal oxide layer on the substrate, adopting a fourth masking process to etch the second transparent metal oxide layer to be a top gate electrode and at least one pixel electrode, the top gate electrode is above the semiconductor pattern, and a portion of the pixel electrode overlaps with the common electrode, and the pixel electrode electrically connects to the source electrode or the drain electrode via the through hole.

9. The manufacturing method as claimed in claim 8, wherein the step of forming a semiconductor layer and a second metal layer on the substrate, adopting a second masking process to etch the semiconductor layer and the second metal layer to form a semiconductor pattern and a source electrode and a drain electrode at two ends of the semiconductor pattern further comprises:
forming an intrinsic semiconductor layer, a doped semiconductor layer, and the second metal layer, adopting the second masking process to etch the intrinsic semiconductor layer to be an intrinsic pattern, to etch the doped semiconductor layer to be a first doped semiconductor pattern and a second doped semiconductor pattern, and to etch the second metal layer to be the drain electrode and the source electrode respectively above the first doped semiconductor pattern and the second doped semiconductor pattern, and the first doped semiconductor pattern and the second doped semiconductor pattern are at two ends of the intrinsic semiconductor layer.

10. The manufacturing method as claimed in claim 9, wherein the second mask is one of half-tone mask (HTM), gray-tone mask (GTM) and single slit mask (SSM).

11. A TFT substrate, comprising:
a substrate; and
a bottom gate electrode and a common electrode on the substrate formed by the same masking process, the bottom gate electrode is of a dual-layer structure comprising the first metal layer and the first transparent metal oxide layer, and the common electrode is of a single-layer structure having the first transparent metal oxide layer.

12. The array substrate as claimed in claim 11, wherein the array substrate further comprises a semiconductor layer above the bottom gate electrode and a source electrode and a drain electrode at two ends of the semiconductor pattern, wherein the semiconductor pattern, the source electrode, and the drain electrode are formed by another masking process.

13. The array substrate as claimed in claim 12, wherein the semiconductor pattern comprises: an intrinsic semiconductor layer, and a first doped semiconductor layer and a second doped semiconductor pattern respectively at two ends of the intrinsic semiconductor layer, and the drain electrode and the source electrode are respectively arranged above the first doped semiconductor pattern and the second doped semiconductor pattern.
